(19) United States
(12) Patent Application Publication
(10) Pub. No.: US 2016/0341381 A1
(43) Pub. Date: Nov. 24, 2016

(54) GUIDANCE APPARATUS AND GUIDANCE SYSTEM

(71) Applicants: Takahiro IMAI, Tokyo (JP); Tsuneaki Kondoh, Kanagawa (JP); Tomoaki Sugawara, Kanagawa (JP); Yuko Arizumi, Kanagawa (JP); Junichiro Natori, Kanagawa (JP); Mizuki Otagiri, Kanagawa (JP); Mayuka Araumi, Tokyo (JP)

(72) Inventors: Takahiro IMAI, Tokyo (JP); Tsuneaki Kondoh, Kanagawa (JP); Tomoaki Sugawara, Kanagawa (JP); Yuko Arizumi, Kanagawa (JP); Junichiro Natori, Kanagawa (JP); Mizuki Otagiri, Kanagawa (JP); Mayuka Araumi, Tokyo (JP)

(21) Appl. No.: 15/145,181

(22) Filed: May 3, 2016

(30) Foreign Application Priority Data
May 18, 2015 (JP) 2015-101145

(51) Int. Cl. F21S 9/04; H02N 2/18; H01L 41/113; F21S 8/00; F21S 8/04

(52) U.S. Cl. CPC F21S 9/04; F21S 8/032; F21S 8/033; F21S 8/046; H01L 41/113; H02N 2/18; F21Y 2103/003

(57) ABSTRACT

Provided is a guidance apparatus including a panel configured to be disposed on at least one of a floor on a predetermined region and a wall on a predetermined region in a passage, an electric-power-generating element configured to be disposed on an opposite side of the panel to a side to which external force is applied, the electric-power-generating element having flexibility, and at least one light source configured to be electrically coupled to the electric-power-generating element.

### CROSS-REFERENCE TO RELATED APPLICATIONS

The present application claims priority under 35 U.S.C. §119 to Japanese Patent Application No. 2015-101145, filed May 18, 2015. The contents of which are incorporated herein by reference in their entirety.

### BACKGROUND OF THE INVENTION

1. Field of the Invention

The present disclosure relates to guidance apparatuses and guidance systems.

2. Description of the Related Art

There has been known an electric-power-generating floor material in which an electric-power-generating element configured to generate electric power utilizing pressure fluctuation is disposed within a panelized floor material. The electric-power-generating floor material is configured to generate electric power utilizing pressure (e.g., human body weight) applied to the floor material, to light a light source using the electric power (see e.g., Japanese Unexamined Patent Application Publication No. 2011-28627).

The Japanese Unexamined Patent Application Publication No. 2011-28627 proposes an evacuation guidance lighting system including a panel, which includes a light source and a piezoelectric sensor (electric-power-generating element), an electric power storage device configured to store electric power generated by the piezoelectric sensor, and a receiver configured to receive an emergency signal for the purpose of evacuating people to an evacuation site safely in evacuation guidance.

### SUMMARY OF THE INVENTION

A guidance apparatus according to the present invention includes a panel, a flexible electric-power-generating element, and at least one light source. The panel is disposed on at least one of a floor at a predetermined region and a wall at a predetermined region in a passage. The flexible electric-power-generating element is disposed on an opposite side of the panel to a side to which external force is applied. The at least one light source is configured to be electrically coupled to the electric-power-generating element.

### BRIEF DESCRIPTION OF THE DRAWINGS

FIG. 1A is a schematic plan view illustrating a guidance apparatus according to one embodiment of the present invention;

FIG. 1B is an end view illustrating the guidance apparatus of FIG. 1A viewed from below;

FIG. 2 is a schematic cross-sectional view illustrating a configuration of an electric-power-generating element used for a guidance apparatus according to the present invention;

FIG. 3 is a graph illustrating an amount of instant electric power generation of a guidance apparatus according to the present invention;

FIG. 4 is a graph illustrating an amount of electric power generation of a flexible electric-power-generating element used in a guidance apparatus according to the present invention (left-hand bar) and an amount of electric power generation of a ceramic electric-power-generating element (right-hand bar);

FIG. 5 is a graph illustrating results of durability tests of a flexible electric-power-generating element used in a guidance apparatus according to the present invention and a ceramic electric-power-generating element;

FIG. 6A is a schematic plan view illustrating a guidance apparatus according to another embodiment of the present invention;

FIG. 6B is an end view illustrating the guidance apparatus of FIG. 6A viewed from below;

FIG. 7 is a schematic plan view illustrating a guidance apparatus according to another embodiment of the present invention;

FIG. 8 is a schematic view illustrating one exemplary wiring of the guidance apparatus of FIG. 7, the guidance apparatus including a relay board;

FIG. 9 is an explanatory view illustrating a lightning state of light sources in a left half of a guidance apparatus under a condition in which two guidance apparatuses of FIG. 8 are continuously coupled to each other;

FIG. 10A is a schematic plan view illustrating a guidance apparatus according to the present invention in which LEDs are obliquely disposed;

FIG. 10B is a side end view illustrating an LED array in the guidance apparatus of FIG. 10A;

FIG. 11 is a schematic view illustrating a condition in which light sources are also disposed on a ceiling; and

FIG. 12 is an arrangement diagram illustrating a guidance system according to one embodiment of the present invention.

### DESCRIPTION OF THE EMBODIMENTS

### (Guidance Apparatus)

A guidance apparatus according to the present invention is disposed in a passage. The guidance apparatus includes a panel, an electric-power-generating element, and at least one light source; and, if necessary, further includes other members.

A place in which the guidance apparatus is disposed is not particularly limited and may be appropriately selected depending on the intended purpose, so long as the place has a region to which external force is applied (e.g., a floor and a wall in the passage). Examples of the place include indoor passages and outdoor passages.

The present invention has an object to provide a guidance apparatus including an electric-power-generating element with high durability and configured to generate a large amount of electric power.

The present invention can provide a guidance apparatus including an electric-power-generating element with high durability and configured to generate a large amount of electric power.

### <Panel>

Shape, structure, size, and material of the panel are not particularly limited and may be appropriately selected depending on the intended purpose, so long as the panel can be disposed at a predetermined region (e.g., the floor and the wall in the passage).

The predetermined region is not particularly limited and may be appropriately selected depending on the intended purpose. When the panel is disposed on the floor in the passage, a width of the predetermined region in a direction orthogonal to a moving direction on the passage is preferably approximately equal to a width of the passage, and a length of the predetermined region in the moving direction on the passage is preferably about 3 m. When the passage has a wall and the panel is disposed on the wall, a height of the predetermined region is not particularly limited and may be appropriately selected depending on the intended purpose, so long as a length of the predetermined region in the moving direction on the passage is about 3 m. The guidance apparatus is advantageously disposed at each predetermined region in the passage because even though the guidance apparatus at a region is damaged or failed after the guidance apparatus is disposed in the passage, only the guidance apparatus at the region has to be replaced.

The shape of the panel is not particularly limited and may be appropriately selected depending on the intended purpose. Examples of the shape include a circular plane, a rectangular plane, and a polygonal plane.

The structure of the panel is not particularly limited and may be appropriately selected depending on the intended purpose. For example, the panel may be divided into a plurality of panels at the predetermined region.

The size of the panel is not particularly limited and may be appropriately selected depending on the intended purpose. For example, the panel may be as large as the predetermined region or the panel is smaller than the predetermined region in order to dispose a plurality of panels at the predetermined region. When the panel is smaller than the predetermined region, size of the panel is not particularly limited and may be appropriately selected depending on the intended purpose. However, the panel preferably has the size of 25 cm×25 cm. When the panel has the size of 25 cm×25 cm, assuming that human has a shoe size of approximately 26 cm and a stride of 40 cm on average, the guidance apparatus can surely generate electric power because each foot is supposed to step on separate panels disposed on the floor.

The material of the panel is not particularly limited and may be appropriately selected depending on the intended purpose. Examples of the material include textiles (e.g., tatami mats and carpets), stone (e.g., tiles), resin materials, natural materials (e.g., wood), and elastic bodies (e.g., rubber).

Notably, the panel may be disposed in any arrangement, so long as the panel is disposed within the predetermined region. For example, a plurality of panels divided may be disposed with or without a gap. The gap is not particularly limited. For example, a plurality of panels may be disposed at equal intervals or a plurality of hexagonal panels are disposed within the predetermined region in order to achieve more sophisticated design.

### <Electric-Power Generating Element>

The electric-power-generating element is disposed on an opposite side of the panel to a side to which pressing force against the panel is applied. The electric-power-generating element includes a first electrode, an intermediate layer, and a second electrode; and, if necessary, further includes other members. The first electrode, the intermediate layer, the second electrode are laminated in this order.

### <<First Electrode and Second Electrode>>

Material, shape, size, and structure of the first electrode and the second electrode are not particularly limited and may be appropriately selected depending on the intended purpose.

The material, shape, size, and structure of the first electrode may be the same as or different from material, shape, size, and structure of the second electrode, but is preferably the same as material, shape, size, and structure of the second electrode.

Examples of the material of the first electrode and the second electrode include metals, carbon-based conductive materials, and conductive rubber compositions.

Examples of the metal include gold, silver, copper, iron, aluminium, stainless, tantalum, nickel, and phosphor bronze.

Examples of the carbon-based conductive material include graphite, carbon fibers, and carbon nanotubes.

Examples of the conductive rubber composition include compositions which contain conductive fillers and rubber.

Examples of the conductive filler include carbon materials (e.g., Ketjen black, acetylene black, graphite, carbon fibers (CF), carbon nanofibers (CNF), and carbon nanotubes (CNT)), metal fillers (e.g., gold, silver, platinum, copper, iron, aluminium, and nickel), conductive polymeric materials (e.g., derivatives of polythiophene, polyacetylene, polyaniline, polypyrrole, polyparaphenylene, or polyparaphenylene vinylene; or these derivatives doped with dopants (e.g., anions or cations)), and ionic liquid. these may be used alone or in combination.

Examples of the rubber include silicone rubber, modified silicone rubber, acrylic rubber, chloroprene rubber, polysulfide rubber, urethane rubber, isobutyl rubber, fluorosilicone rubber, ethylene rubber, and natural rubber (latex). These may be used alone or in combination.

The first electrode and the second electrode may be in a sheet, film, thin film, woven, nonwoven, mesh, or sponge form. Notably, the first electrode and the second electrode may be nonwoven in which fibrous carbon materials are entangled.

Examples of the film include conductive films.

Examples of the conductive films include conductive films in which metallic foil is attached on polymeric films. The polymeric film may be commercially available products. Examples of the commercially available product include ALPET 9-100 and ALPET 25-25 (both products are of PANAC CO., LTD.).

The shape of the first electrode and the second electrode is not particularly limited and may be appropriately selected depending on shape of the electric-power-generating element.

The size of the first electrode and the second electrode is not particularly limited and may be appropriately selected depending on size of the electric-power-generating element.

Average thickness of the first electrode and the second electrode is not particularly limited and may be appropriately selected depending on structure of the electric-power-generating element, but is preferably in a range of from 0.01 μm through 1 mm, more preferably in a range of from 0.1 μm through 500 μm from the viewpoints of conductivity and flexibility. When the average thickness is 0.01 μm or more, mechanical strength is proper and conductivity is improved. When the average thickness is 1 mm or less, the electric-power-generating element can be deformed and electric-power-generating capacity is good.

### <<Intermediate Layer>>

The intermediate layer is disposed between the first electrode and the second electrode. The intermediate layer is deformed by external force to generate electric power. The intermediate layer may or may not adhere to the first electrode and the second electrode.

Material, shape, size, and structure of the intermediate layer are not particularly limited and may be appropriately selected depending on the intended purpose.

Examples of the material of the intermediate layer include barium titanate, lead zirconate titanate (PZT), polyvinylidene fluoride (PVDF), fluororesin, rubber, and rubber compositions. Of these, preferable are the rubber and the rubber compositions because the rubber and the rubber compositions are easily deformed with low external force.

Examples of the rubber include silicone rubber, fluorosilicone rubber, fluororubber, urethane rubber, acrylic rubber, chloroprene rubber, butyl rubber, ethylene-propylene rubber, nitrile, polysulfide rubber, and natural rubber (latex). Of these, preferable is the silicone rubber from the viewpoint of high electric-power generating capacity.

The silicone rubber is not particularly limited and may be appropriately selected depending on the intended purpose, so long as the silicone rubber contains an organopolysiloxane bond.

Examples of the silicone rubber include dimethylsilicone rubber, methylphenylsilicone rubber, modified silicone rubber (e.g., acrylic modified rubber, alkyd modified rubber, ester modified rubber, and epoxy modified rubber). These may be used alone or in combination.

The intermediate layer made of the rubber can microscopically move in a direction parallel to a surface of the first electrode and a surface of the second electrode when the intermediate layer is pressed in a vertical direction.

Notably, the first electrode and the second electrode, and/or the intermediate layer made of the rubber may be movable. This enables the intermediate layer, which is at least partially made of the rubber, to move in the direction parallel to the surface of the first electrode and the surface of the second electrode even though the first electrode and the second electrode are secured to the intermediate layer made of the rubber at a peripheral portion, because the first electrode, the second electrode, and the intermediate layer made of the rubber each has flexibility.

A mechanism by which the electric-power-generating element including the intermediate layer made of the rubber composition generates electric power has not been exactly clarified, but is presumed as follows. The intermediate layer adjacent to the electrode is moved in the direction parallel to the surface of the first electrode and the surface of the second electrode by the action of a load applied (e.g., external force or vibration) to be charged through a mechanism induced by frictional charging. Alternatively, charges are generated within the intermediate layer made of the rubber to cause a surface potential difference. As a result, the charges are moved so that the surface potential difference is zero, resulting in generating electric power.

The intermediate layer made of the rubber may contain a filler for the purpose of imparting various functions to the intermediate layer. Examples of the filler include titanium oxide, barium titanate, lead zirconate titanate, zinc oxide, silica, calcium carbonate, carbon black, carbon nanotubes, carbon fibers, iron oxide, PTFE, mica, clay minerals, synthetic hydrotalcite, and metals. When piezoelectric fillers or polarized polymeric fillers are used, the intermediate layer is preferably polarized.

The intermediate layer made of the rubber preferably has hardness (JIS-A hardness) of less than 60°, more preferably 52° or less, particularly preferably 42° or less. When the hardness is less than 60°, the intermediate layer is not prevented from moving, leading to good electric power generation.

Average thickness of the intermediate layer made of the rubber is not particularly limited and may be appropriately selected depending on the intended purpose, but is preferably in a range of from 1 μm through 10 mm, more preferably 50 μm through 200 μm from the viewpoint of deformation followability. When the average thickness falls within the preferable range, the intermediate layer can surely have a film forming property and is not prevented from deforming, leading to good electric power generation.

The intermediate layer made of the rubber preferably has an insulating property. The intermediate layer preferably has volume resistivity of 10⁸ Ωcm or more, more preferably 10¹⁰ Ωcm or more.

The intermediate layer made of the rubber has a multi-layered structure.

### —Surface Modification Treatment and Inactivation Treatment—

Examples of a method for changing a moving length or surface hardness of the intermediate layer made of the rubber include surface modification treatments and inactivation treatments. The intermediate layer may be subjected to both or one of the treatments described above.

### —Surface Modification Treatment—

Examples of the surface modification treatment include plasma treatments, corona discharge treatments, electron beam irradiation treatments, ultraviolet irradiation treatments, ozone treatments, and radiation (X rays, α rays, β rays, γ rays, or neutron rays) irradiation treatments. Of these, preferable are the plasma treatments, the corona discharge treatments, and the electron beam irradiation treatments from the viewpoint of treatment velocity. However, the surface modification treatment is not limited thereto, so long as the treatment has a certain degree of irradiation energy and can modify the material of the intermediate layer.

### —Plasma Treatment—

In the case of the plasma treatment, for example, parallel-plate plasma generators, capacitively-coupled plasma generators, or inductively-coupled plasma generators can be used. Additionally, atmospheric pressure plasma generators can also be used. A plasma treatment method is preferably reduced-pressure plasma treatments from the viewpoint of durability.

Reaction pressure in the plasma treatment is not particularly limited and may be appropriately selected depending on the intended purpose, but is preferably in a range of from 0.05 Pa through 100 Pa, more preferably in a range of from 1 Pa through 20 Pa.

A reaction atmosphere in the plasma treatment is not particularly limited and may be appropriately selected depending on the intended purpose. For example, gases (e.g., inert gas, noble gas, and oxygen) are effective. Argon is preferable from the viewpoint of a long-lasting effect. In this case, oxygen partial pressure is preferably 5,000 ppm or less. When the oxygen partial pressure in the reaction atmosphere is 5,000 ppm or less, ozone can be prevented from generating, which can eliminate the need for ozone treatment devices.

Irradiated electric energy in the plasma treatment is defined as (output×irradiation time). The irradiated electric energy is preferably in a range of from 5 Wh through 200 Wh, more preferably in a range of from 10 Wh through 50 Wh. When the irradiated electric energy falls within the preferable range, the intermediate layer can attain an electric-power-generating function and can be prevented from deteriorating in durability due to excessive irradiation.

### —Corona Discharge Treatment—

Applied energy (cumulative energy) in the corona discharge treatment is preferably in a range of from 6 J/cm² through 300 J/cm², more preferably in a range of from 12 J/cm² through 60 J/cm². When the applied energy falls within the preferable range, the intermediate layer can attain an electric-power-generating function and can be prevented from deteriorating in durability due to excessive irradiation.

### —Electron Beam Irradiation Treatment—

Irradiation dose in the electron beam irradiation treatment is preferably 1 kGy or more, more preferably in a range of from 300 kGy through 10 MGy. When the irradiation dose falls within the preferable range, the intermediate layer can attain an electric-power-generating function and can be prevented from deteriorating in durability due to excessive irradiation.

A reaction atmosphere in the electron beam irradiation treatment is not particularly limited and may be appropriately selected depending on the intended purpose, but is preferably filled with inert gases (e.g., argon, neon, helium, and nitrogen) so as to have the oxygen partial pressure of 5,000 ppm or less. When the oxygen partial pressure in the reaction atmosphere is 5,000 ppm or less, ozone can be prevented from generating, which can eliminate the need for ozone treatment devices.

### —Ultraviolet Irradiation Treatment—

Ultraviolet in the ultraviolet irradiation treatment preferably has a wavelength in a range of from 200 nm through 365 nm, more preferably in a range of from 240 nm through 320 nm.

Cumulative dose in the ultraviolet irradiation treatment is preferably in a range of from 5 J/cm² through 500 J/cm², more preferably in a range of from 50 J/cm² through 400 J/cm². When the cumulative dose falls within the preferable range, the intermediate layer can attain an electric-power-generating function and can be prevented from deteriorating in durability due to excessive irradiation.

A reaction atmosphere in the ultraviolet irradiation treatment is not particularly limited and may be appropriately selected depending on the intended purpose, but is preferably filled with inert gases (e.g., argon, neon, helium, and nitrogen) so as to have the oxygen partial pressure of 5,000 ppm or less. When the oxygen partial pressure in the reaction atmosphere is 5,000 ppm or less, ozone can be prevented from generating, which can eliminate the need for ozone treatment devices.

In the related art, it has been proposed to generate active groups through excitation or oxidation by the plasma treatment, the corona discharge treatment, the ultraviolet irradiation treatment, or the electron beam irradiation treatment, for the purpose of enhancing adhesion force between layers. However, this method can be applied to only between layers. On the contrary, it has been found that it is not preferable to apply this method to the outermost surface from the viewpoint of reduced releasability. Additionally, in this method, reactive groups (hydroxyl groups) are effectively introduced by allowing to react under an oxygen-rich atmosphere. Thus, this method is essentially different from the surface modification treatment according to the present invention.

The surface modification treatment is performed under an oxygen-poor reaction environment at reduced pressure (e.g., plasma treatment). Therefore, re-crosslinking and re-bonding at the surface are accelerated to improve durability due to “increased Si—O bonds having high bonding energy,” and to improve releasability due to “densification due to increased cross-linking density.” Notably, some active groups are generated, but the active groups are inactivated by treating with a coupling agent or by air drying.

A surface treated layer obtained by the surface treatment preferably has average thickness in a range of from 0.01 μm through 50 μm, more preferably in a range of from 0.01 μm through 20.0 μm. When the average thickness falls within the preferable range, the intermediate layer can attain an electric-power-generating function and can be prevented from increasing in hardness or from decreasing in amount of electric power generation.

### —Inactivation Treatment—

A surface of the intermediate layer made of the rubber may be appropriately subjected to an inactivation treatment using various materials.

The inactivation treatment is not particularly limited and may be appropriately selected depending on the intended purpose, so long as the surface of the intermediate layer made of the rubber is inactivated. For example, an inactivating agent may be applied onto the surface of the intermediate layer. The term inactivation means rendering the surface of the intermediate layer made of the rubber less susceptible to chemical reactions by allowing active groups (e.g., —OH groups), which are generated through excitation or oxidation by, for example, the plasma treatment, the corona discharge treatment, the ultraviolet irradiation treatment, or the electron beam irradiation treatment, to react with the inactivating agent to decrease surface activity of the intermediate layer made of the rubber.

Examples of the inactivating agent include amorphous resins and coupling agents.

Examples of the amorphous resin include resin containing a perfluoropolyether structure in a main chain.

Examples of the coupling agent include metal alkoxides and metal-alkoxide containing solutions. Examples of the metal alkoxide include compounds represented by General Formula (1) described below, partially hydrolyzed polycondensates (the degree of polymerization: from 2 through 10) of the compounds, or mixtures of the compounds:

R¹₍₄₋ₙ₎Si(OR²)ₙ General Formula (1).

In the General Formula (1), R¹ and R² each independently denotes straight-chained or branched alkyl groups having from 1 through 10 carbon atoms, alkylpolyether chains, or aryl groups; and n denotes an integer in a range of from 2 through 4.

Specific examples of the compound represented by the General Formula (1) include dimethyldimethoxysilane, diethyldiethoxysilane, diethyldimethoxysilane, diethyldiethoxysilane, diphenyldimethoxysilane, diphenyldiethoxysilane, methyltrimethoxysilane, methyltriethoxysilane, tetramethoxysilane, tetraethoxysilane, and tetrapropoxysilane. Particularly preferable is tetraethoxysilane from the viewpoint of durability.

In the General Formula (1), R¹ may be fluoroalkyl groups, as well as fluoroalkylacrylate groups which are bound via oxygen or perfluoropolyether groups. Particularly preferable is the perfluoropolyether group from the viewpoint of flexibility and durability.

Examples of the metal alkoxide include vinylsilanes [e.g., vinyltris(β-methoxyethoxy)silane, vinyltriethoxysilane, and vinyltrimethoxysilane], acrylic silanes [e.g., γ-methacryloxypropyltrimethoxysilane], epoxysilanes [e.g., β-(3,4-epoxycyclohexl)ethyltrimethoxysilane, γ-glycidoxypropyltrimethoxysilane, γ-glycidoxypropylmethyldiethoxysilane], amino silanes [N-β(aminoethyl) γ-aminopropyltrimethoxysilane, N-β(aminoethyl) γ-aminopropylmethyldimethoxysilane, γ-aminopropyltriethoxysilane, and N-phenyl-γ-aminopropyltrimethoxysilane].

In the metal alkoxide, metal atoms other than Si (e.g., Ti, Sn, Al, and Zr) may be used alone or in combination.

The inactivation treatment may be performed by subjecting a precursor of the intermediate layer made of the rubber to the surface modification treatment and then impregnating a surface of the precursor of the intermediate layer made of the rubber with the inactivating agent through, for example, coating or dipping.

When silicone rubber is used as the precursor of the intermediate layer made of the rubber, the inactivation treatment may be performed by subjecting the precursor to the surface modification treatment and then leaving to stand in the air to air-dry.

### <Other Members>

The other members are not particularly limited and may be appropriately selected depending on the intended purpose. Examples of the other members include sealing layers.

### <<Sealing Layer>>

The sealing layer may be disposed on opposite surfaces of the first electrode and the second electrode to surfaces facing the intermediate layer.

The sealing layer is not particularly limited and may be appropriately selected depending on the intended purpose. Examples of the sealing layers include cellophane tapes.

The intermediate layer made of the rubber preferably has no initial surface potential in a standing state.

Notably, the initial surface potential in a standing state can be measured under the measurement condition described below. The phrase “no initial surface potential” means the initial surface potential of ±10 V or less when the initial surface potential is measured under the measurement conditions described below.

### [Measurement Conditions]

Pretreatment: Leaving to stand for 24 hours under an atmosphere of a temperature of 30° C. and relative humidity of 40%, and then charge elimination for 60 seconds using SJ-F300 (product of KEYENCE CORPORATION).

Device: TRECK Model 344

Measurement probe: 6000B-7C

Measurement distance: 2 mm

Measurement spot diameter: 10 mm

### <Light Source>

The light source may be a single light source or a group of light sources including a plurality of light sources, so long as the light source is electrically coupled to the electric-power-generating element and can emit light with electric power generated by the electric-power-generating element. Shape, configuration, size, type, and disposed position of the light source are not particularly limited and may be appropriately selected depending on the intended purpose.

The shape of the light source is not particularly limited and may be appropriately selected depending on the intended purpose.

The configuration of the light source is not particularly limited and may be appropriately selected depending on the intended purpose. For example, the light source may be a light emitting diode (LED) array including a plurality of LEDs, that is, the group of light sources including the plurality of light sources.

### <<LED Array>>

A configuration of the LED array is not particularly limited and may be appropriately selected depending on the intended purpose. Examples of the configuration include a configuration in which the LEDs are disposed in a row, a configuration in which the LEDs are disposed in a plurality of rows, and a configuration in which the LEDs are nested.

The configuration in which the LEDs are arranged in a row is not particularly limited and may be appropriately selected depending on the intended purpose. Examples of the configurations include a configuration including a first group of light sources which are disposed obliquely to the same direction as the moving direction on the passage and the second group of light sources which are disposed obliquely to an opposite direction to the moving direction on the passage and a configuration including a first group of light sources which are disposed obliquely to an opposite direction to the moving direction on the passage and a second group of light sources which are disposed obliquely to the same direction as the moving direction on the passage. In the case of a LED array in which both of the first group of light sources and the second group of light sources are obliquely disposed, people can be guided according to a color of light emitted from the LEDs by allowing LEDs of the first group of light sources to emit light having a different color from a color of light emitted from LEDs of the second group of light sources. For example, in the case where a color of light emitted from a group of light sources which are disposed obliquely toward an opposite direction to the moving direction is green, and a color of light emitted from of a group of light sources which are disposed obliquely toward the same direction as the moving direction is red, people can recognize green light when the people face the moving direction and people can recognize red light when the people face the opposite direction to the moving direction.

The configuration in which the LEDs are disposed in a plurality of rows is not particularly limited and may be appropriately selected depending on the intended purpose. Examples of the configuration include a configuration in which the LEDs are disposed in two rows and a configuration in which the plurality of LEDs are disposed so as to form a sign (e.g., arrow) or a design.

Examples of the configuration in which the LEDs are disposed in two rows include a configuration in which a group of light sources in one row (which may be referred to as a third group of light sources) are coupled to the electric-power-generating element in the guidance apparatus which is different from the guidance apparatus coupled to a group of light sources in the other row (which may be referred to as a fourth group of light sources); a configuration including the first group of light sources which are disposed obliquely to the same direction as the moving direction on the passage and the second group of light sources which are disposed obliquely to an opposite direction to the moving direction on the passage; and a configuration including the first group of light sources which are disposed obliquely to an opposite direction to the moving direction on the passage and the second group of light sources which are disposed obliquely to the same direction as the moving direction on the passage.

The configuration in which the plurality of LEDs are disposed so as to form a sign (e.g., arrow) or a design is not particularly limited and may be appropriately selected depending on the intended purpose. For example, the LEDs are preferably disposed at a position where people can easily recognize light emitted from the LEDs (e.g., an upper surface of the panel).

The size of the light source is not particularly limited and may be appropriately selected depending on the intended purpose.

The type of the light source is not particularly limited and may be appropriately selected depending on the intended purpose. For example, the light source may be the LEDs, light bulbs, and fluorescent lamps.

The disposed position of the light source is not particularly limited and may be appropriately selected depending on the intended purpose. For example, the light source may be disposed anywhere on a peripheral edge of the panel, an upper surface of the panel, the wall adjacent to the guidance apparatus, and the ceiling in the passage. In the case where the light source is disposed anywhere on the peripheral edge of the panel, for example, the light source may be disposed on the peripheral edge so that the peripheral edge is in parallel to the moving direction on the passage when the guidance apparatus is disposed.

### <Other Members>

The other members are not particularly limited and may be appropriately selected depending on the intended purpose. Examples of the other members include lower floor materials disposed under the electric-power-generating element and relay boards configured to relay wires coupled to the electric-power-generating element.

### <<Lower Floor Material>>

Shape, structure, size, and material of the lower floor material are not particularly limited and may be appropriately selected depending on the intended purpose, so long as the lower floor material is disposed under the electric-power-generating element.

The shape of the lower floor material is not particularly limited and may be appropriately selected depending on the intended purpose. For example, the lower floor material may has the same shape as the predetermined region or as the panel.

The structure of the lower floor material is not particularly limited and may be appropriately selected depending on the intended purpose.

The size of the lower floor material is not particularly limited and may be appropriately selected depending on the intended purpose. For example, the lower floor material may be as large as the panel or may have the size of 25 cm×25 cm, depending on the size of the panel.

The material of the lower floor material is not particularly limited and may be appropriately selected depending on the intended purpose. For example, the lower floor material can preferably secure and protect the electric-power-generating element using elastic bodies such as synthetic resin and rubber.

### <<Relay Board>>

Shape, structure, size, and disposed position of the relay board are not particularly limited and may be appropriately selected depending on the intended purpose, so long as the relay board can relay the wires coupled to the electric-power-generating element.

The shape of the relay board is not particularly limited and may be appropriately selected depending on the intended purpose.

The structure of the relay board is not particularly limited and may be appropriately selected depending on the intended purpose. For example, commercially available relay boards may be used.

The size of the relay board is not particularly limited and may be appropriately selected depending on the intended purpose, but is preferably small as possible because the relay board only has to relay the wires.

The disposed position of the relay board is not particularly limited and may be appropriately selected depending on the intended purpose. For example, the relay board may be disposed between the electric-power-generating element and the light source.

### (Guidance System)

The guidance system includes the guidance apparatus according to the present invention; and, if necessary, further includes transmitters, acoustic devices, and further other devices.

### <Transmitter>

Shape, structure, size, and disposed position of the transmitter are not particularly limited and may be appropriately selected depending on the intended purpose, so long as the transmitter can be coupled to the electric-power-generating element to transmit any data to other devices and other systems using electric power generated by the electric-power-generating element.

The shape of the transmitter is not particularly limited and may be appropriately selected depending on the intended purpose.

The structure of the transmitter is not particularly limited and may be appropriately selected depending on the intended purpose, so long as the transmitter can transmit any data to the other devices and the other systems using electric power generated by the electric-power-generating element.

The size of the transmitter is not particularly limited and may be appropriately selected depending on the intended purpose.

The disposed position of the transmitter is not particularly limited and may be appropriately selected depending on the intended purpose. For example, the transmitter may be disposed under the LED array included in the guidance apparatus.

Examples of the transmitter include a transmitter configured to transmit data, which informs that electric power is generated, to an emergency system using the electric power generated by the electric-power-generating element, the emergency system being configured to create, based on the data, evacuation data informing the presence of a person in the guidance apparatus where electric power is generated; and a transmitter configured to transmit data, which informs that electric power is generated, to a decorative system using the electric power generated by the electric-power-generating element, the decorative system being configured to control, based on the data, to decorate adjacent to the guidance apparatus where electric power is generated.

### <Acoustic Device>

Shape, structure, size, and disposed position of the acoustic device are not particularly limited and may be appropriately selected depending on the intended purpose, so long as the acoustic device can be coupled to the electric-power-generating element to make a sound using electric power generated by the electric-power-generating element.

The shape, structure, and size of the acoustic device are not particularly limited and may be appropriately selected depending on the intended purpose.

The disposed position of the acoustic device is not particularly limited and may be appropriately selected depending on the intended purpose. For example, the acoustic device may be disposed under the LED array included in the guidance apparatus or adjacent to the guidance apparatus.

In the case where the guidance system includes the acoustic device, when the guidance apparatus generates electric power, the light source in the guidance apparatus emits light and, at the same time, the acoustic device can make sound effects or evacuation announcements synchronized with the light. For example, a highly decorative guidance system can be made by expressing a water surface of a river using the plurality of light sources and making sound effects as if people are walking on the water surface.

### <Other Devices>

The other devices are not particularly limited and may be appropriately selected depending on the intended purpose. Examples of the other devices include electric power storage devices included in the guidance system including at least one of the transmitter and the acoustic device.

### <<Electric Power Storage Device>>

Shape, structure, size, and disposed position of the electric power storage device are not particularly limited and may be appropriately selected depending on the intended purpose, so long as the electric power storage device can be coupled to the electric-power-generating element in the guidance apparatus to store electric power generated by the electric-power-generating element. For example, the electric power storage device may be batteries.

The shape, structure, and size of the electric power storage device are not particularly limited and may be appropriately selected depending on the intended purpose.

The disposed position of the electric power storage device is not particularly limited and may be appropriately selected depending on the intended purpose. For example, the electric power storage device may be disposed under the light source included in the guidance apparatus.

### (Embodiments of Guidance Apparatus)

Embodiments of the present invention will now be described referring to drawings, but the present invention is not limited to the embodiments. Notably, referential numerals such as “1” in each drawing denote the same one as each other.

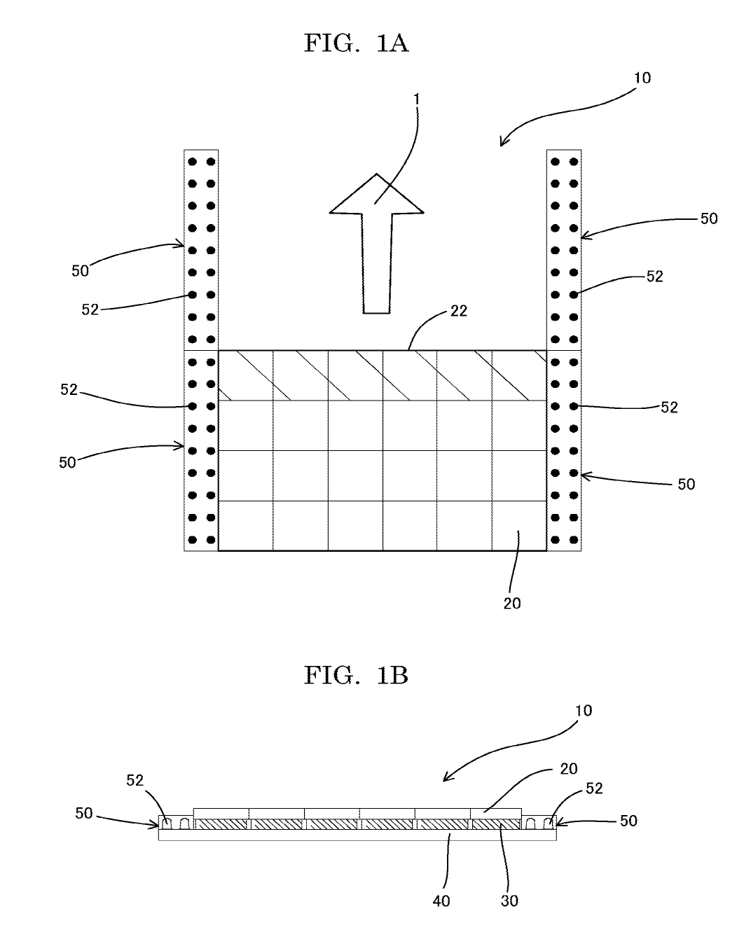

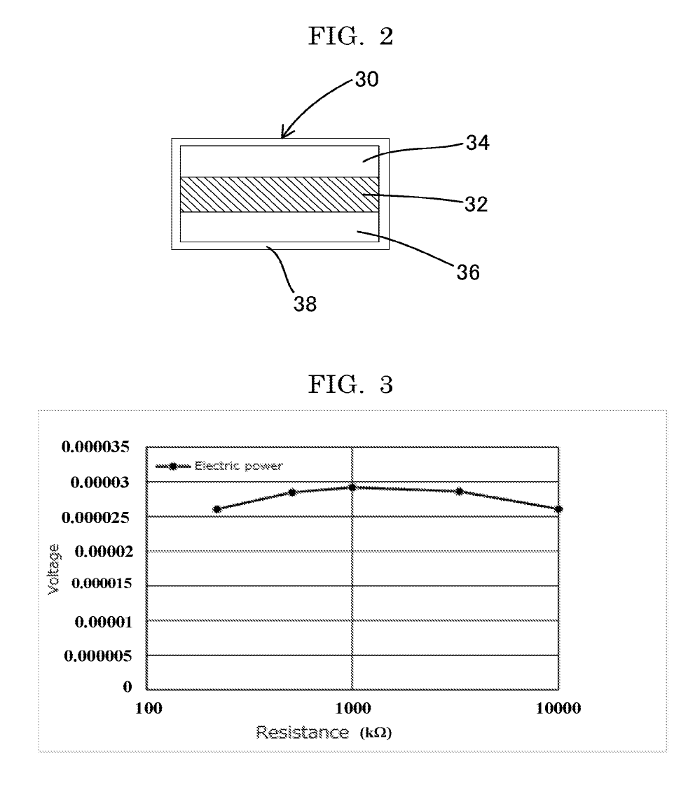

FIG. 1A is a schematic plan view illustrating a guidance apparatus according to one embodiment of the present invention. FIG. 1B is an end view illustrating the guidance apparatus of FIG. 1A viewed from below. FIG. 2 is a schematic cross-sectional view illustrating a configuration of an electric-power-generating element.

As illustrated in FIGS. 1A and 1B, a guidance apparatus 10 according to the present invention includes a panel 20 configured to be disposed at a predetermined region, an electric-power-generating element 30, a lower floor material 40, and a light source 52. The electric-power-generating element 30 is disposed under the panel 20. The lower floor material 40 is disposed under the electric-power-generating element 30. The guidance apparatus 10 illustrated in FIGS. 1A and 1B includes an LED array 50 including a plurality of light sources (i.e., LEDs) 52.

In this embodiment, as illustrated in FIGS. 1A and 1B, a plurality of panes 20 are disposed without a gap.

The electric-power-generating element 30 is disposed under each panel 20 as illustrated in FIG. 1B, and has a rectangular cross-section. As illustrated in FIG. 2, the electric-power-generating element 30 includes a piezoelectric body 32, which has flexibility and serves as the intermediate layer. The piezoelectric body 32 is sandwiched between an upper electrode (first electrode) 34 and a lower electrode (second electrode) 36 and then covered with an insulating body 38 by subjecting a periphery to an insulating treatment. Thus, the electric-power-generating element is formed. A material of the piezoelectric body 32 is a mixture of 100 parts of silicone rubber (TSE3033: product of Momentive Performance Materials Inc.) and 40 parts of barium titanate (93-5640, product of Wako Pure Chemical Industries, Ltd.) serving as an additive. Notably, the electric-power-generating element 30 illustrated in FIG. 1B is approximately as large as the panel 20, but, regardless of the size of the panel 20, the electric-power-generating element may have size so as to be disposed across a plurality of panels 20 or may be much smaller than the panel 20. An electric-power-generating element made of a fragile material (e.g., ceramics) may disadvantageously be broken due to applied pressure when used in the guidance apparatus 10 according to the present invention. However, the electric-power-generating element 30 used in the guidance apparatus 10 according to the present invention includes the piezoelectric body 32 having flexibility. As a result, the electric-power-generating element is not broken due to applied pressure, making it possible to stably generate electric power. Notably, when the panel 20 is made of a flexible material, a plurality of electric-power-generating elements 30 which are approximately as large as the panel 20 are preferably disposed in order to allow the light source 52 to surely emit light. When the plurality of electric-power-generating elements 30 are disposed as illustrated in FIG. 1B, the plurality of electric-power-generating elements 30 may be coupled in series, in parallel, or in series-parallel combination. However, the electric-power-generating element 30 is preferably coupled in parallel in the light of the principle of electric power generation in which charge transfer is caused to force a current to flow.

In this embodiment, the lower floor material 40 is disposed under the electric-power-generating element 30 as illustrated in FIG. 1B in order to secure and protect the electric-power-generating element 30. Notably, the lower floor material 40 is optional.

As illustrated in FIG. 1A, the light sources form the LED array 50 including a plurality of LEDs 52. The LED array 50 may be mounted on an electronic circuit board made of, for example, glass epoxy or EPC, or coupled via an electric wire (e.g., lead wire). The LEDs included in the LED array 50 may be coupled in series, in parallel, or in series-parallel combination. However, the LEDs are preferably coupled in series in the light of the principle of electric power generation by the electric-power-generating element 30. The LEDs preferably have directivity of 120° or more so as to illuminate a wider area. Meanwhile, when only a certain direction is to be recognized, the directivity is preferably 60° or less.

Notably, the LED array 50 is disposed lateral to the panel 20 in FIGS. 1A and 1B, but a disposed position of the LED array is not particularly limited and may be appropriately selected depending on the intended purpose. For example, when the guidance apparatus 10 is disposed in a passage which includes a wall and a ceiling, the LED array may be disposed on the wall or the ceiling. Alternatively, the LED array may be processed so as not to be broken even when pressure is applied and then disposed on an upper surface of the panel 20. The LED array 50 having a decorative design may be disposed on the upper surface of the panel 20 so that light is emitted in accordance with the decorative design every time when pressure is applied to the panel 20 and the electric-power-generating element 30 generates power, in order to provide a better visual effect. In this case, the LED array exhibits a better effect when disposed at a lower position as possible because people tend to look downward in the dark.

As illustrated in FIG. 1A, the LED array 50 according to the present embodiment extends in the moving direction longer than the panel 20, but an extending length of the LED array may be adjusted in accordance with the passage where the LED array is disposed, of course. Notably, an arrow 1 illustrated in FIG. 1A denotes the moving direction in the guidance apparatus 10, and the LED array 50 extends in the moving direction longer than the panel 20. This enables the moving direction to be distinctly recognized even when pressure is applied to the electric-power-generating element 30 disposed adjacent to a moving direction edge 22 of the panel 20, assuming that the LED array 50 is as long as the panel 20. The LED array 50 preferably extends in the moving direction from 1.5 times through 2 times, more preferably about 2 times as long as an extending length of the panel 20 in the moving direction. When the LED array 50 excessively extends, the number of LEDs 52 is increased, and thus, the amount of electric power generation required to light the LEDs 52 is disadvantageously increased.

For example, when the LED array 50 is formed by the LEDs 52 disposed in two rows, the extending length of the panel 20 is preferably 1 m or more but 3 m or less in the moving direction.

FIG. 3 is a graph illustrating an amount of instant electric power generation of the guidance apparatus 10 according to the present invention.

As illustrated in FIG. 3, electric power tends to decrease from a resistance value of about 1 MΩ. Depending on an interval between LEDs serving as the light source 52, the resistance value reaches about 1 MΩ in a distance of about 4 m when the LEDs are disposed at the interval of 7.5 cm in the moving direction or in a distance of about 12 m when the LEDs are disposed at the interval of 20 cm in the moving direction. The resistance value of more than 1 MΩ decreases electric power generated, making it impossible to ensure electric power enough to light all of the LEDs. Thus, the LEDs become difficult to light. The distances of 4 m and 12 m denote a distance of round trip. Therefore, in order to light the LED array 50 over a distance of 6 m, which is half of the distance of 12 m, the extending length of the panel 20 in the moving direction is preferably 3 m or less, which is half of the extending length of the LED array. When the extending length of the panel 20 in the moving direction is excessively short, the LED array 50 illuminates only a narrower area. In particular, people cannot recognize a corner in advance, so that a route is difficult to recognize. Therefore, the extending length of the panel in the moving direction is preferably 1 m or longer.

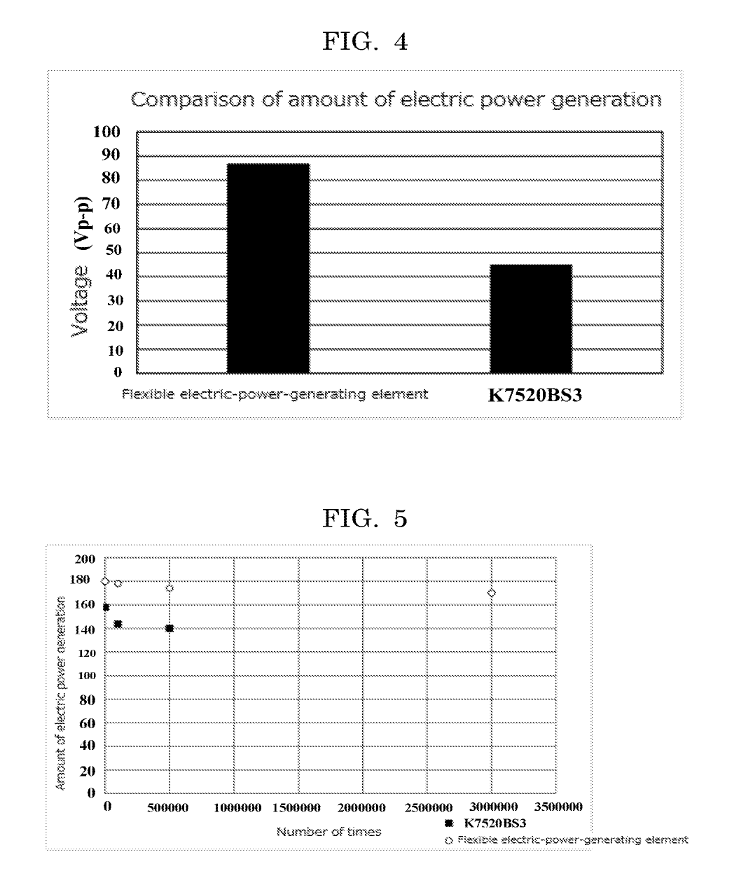

FIG. 4 is a graph illustrating an amount of electric power generation of a flexible electric-power-generating element used in a guidance apparatus according to the present invention (left-hand bar) and an amount of electric power generation of a ceramic electric-power-generating element (right-hand bar).

The amounts of electric power generation were measured using an oscilloscope (input impedance: 1 MΩ) when a SUS ball (R-2F, 200 g) was dropped down from a height of 50 mm. Notably, the ceramic electric-power-generating element was K7520BS3 (product of THRIVE). The K7520BS3 was used with a protective stopper structure so as not to be broken.

As illustrated in FIG. 4, when the flexible electric-power-generating element 30 is used, the amount of electric power generation is increased compared with when the ceramic electric-power-generating element is used.

As such, the use of the flexible electric-power-generating element 30 eliminates the need for a protective mechanism in the electric-power-generating element 30 itself, as well as an electric power storage device because the amount of electric power generation is increased. Additionally, the need to switch between charge and discharge modes of an electric power storage mechanism in the electric power storage device is eliminated, so that the need for a device and mechanism for sensing an emergency are also eliminated, resulting in the guidance apparatus 10 with a simplified structure. There is no knowing what will happen in an emergency. Therefore, when a device with a complex structure is used, a portion of the device may fail to function. However, the guidance apparatus 10 according to the present invention has a simple structure, so that the apparatus can prevent the risk as described above. As a result, reliable, inexpensive guidance apparatuses can be provided.

Notably, the guidance apparatus 10 according to the present invention may include a rectifier circuit configured to rectify electric power generated by the electric-power-generating element 30. The rectifier circuit may be disposed in each electric-power-generating element 30 or at a coupling port to the LED array 50.

Additionally, as a reference, FIG. 5 is a graph illustrating results of durability tests of the flexible electric-power-generating element used in the guidance apparatus according to the present invention (i.e., the electric-power-generating element used in the experiment in FIG. 4) and the ceramic electric-power-generating element K7520BS3.

The durability tests were performed by repeatedly applying a load of pressure of 50 N and displacement of 4 mm at 10 Hz (10 times per second) using a probe having a diameter of 10 mm without the protective mechanism.

As the flexible electric-power-generating element used in the guidance apparatus according to the present invention, an electric-power-generating element including an upper electrode, a lower electrode, and an intermediate layer (conductive fabric SUI-10-70 (product of SEIREN Co., Ltd.)) was used. This electric-power-generating element was subjected to an insulation treatment by wrapping the intermediate layer with a PET film (T type LUMILAR (product of PANAC CO., LTD.)) together with the electrodes.

The electric-power-generating element used in the guidance apparatus according to the present invention was decreased in output by only less than 10% even after the electric-power-generating element was subjected to the test of three million times, as illustrated in FIG. 5. After the test, the PET film used for the insulation treatment was deformed. Therefore, all components other than the electric-power-generating element were replaced and the amount of electric power generation was measured again. As a result, the amount of electric power generation equal to the amount of electric power generation at the beginning of the durability test was achieved. That is, the decrease in output was not due to the electric-power-generating element itself.

On the other hand, the electric-power-generating element K7520BS3 (product of THRIVE) was gradually decreased in output from the beginning of the test when the K7520BS3 was subjected to the durability test in the same manner as described above. After the test of about 500 thousand times, the test was terminated because a lead wire extended from the electric-power-generating element was cut. At this time point, the output was decreased by about 10% relative to the beginning of the test. Although a new lead wire was coupled to the electrode and the amount of electric power generation was measured again, the output remained lower by about 10% than the output at the beginning of the test.

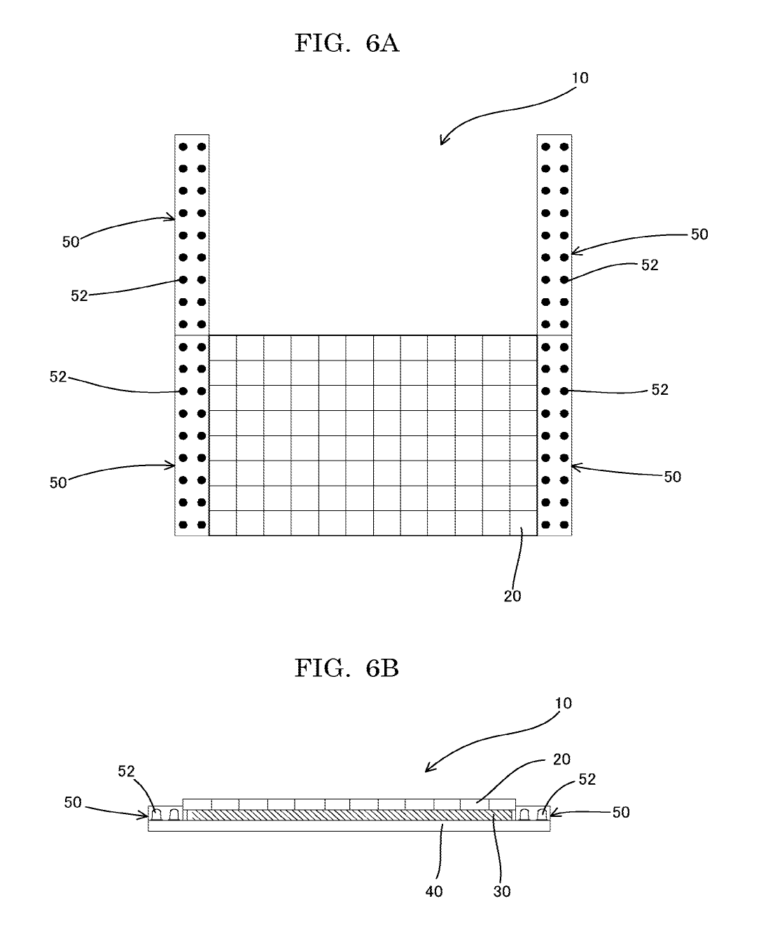

As illustrated in FIGS. 6A and 6B, the electric-power-generating element 30 may be larger than the panel 20 so as to cover over the whole predetermined region. The electric-power-generating element 30 is not broken even when pressure is applied to a portion of the electric-power-generating element because the electric-power-generating element has flexibility. The electric-power-generating element can be produced so as to have a desired area, and therefore, only one electric-power-generating element 30 may be included in the guidance apparatus 10. It is advantageous to include only one electric-power-generating element 30 in the guidance apparatus 10 as illustrated in FIGS. 6A and 6B, because the guidance apparatus 10 can be easily assembled and constructed, and the guidance apparatus 10 can be produced at a lower cost. Additionally, electric power can be generated to light the light source whenever any pressure is applied anywhere within the predetermined region, because the electric-power-generating element 30 is disposed over the whole predetermined region.

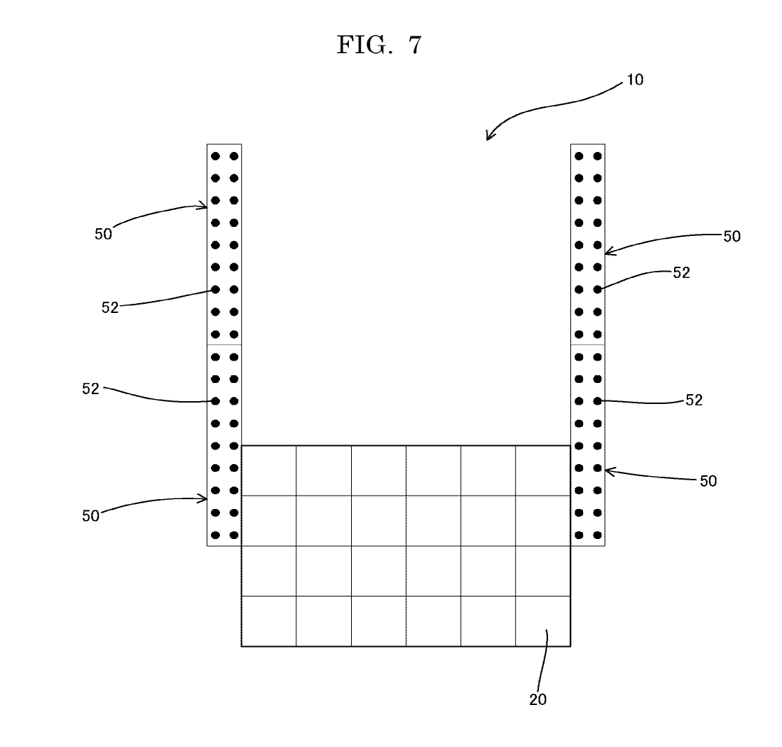

As illustrated in FIG. 7, the LED array 50 may be disposed from a halfway of the panel 20. This is because people are more likely to look at the LED 52 located forward in the moving direction than the LED 52 located just beside the people when the people are on the panel 20. Therefore, it can be said that the LED 52 located forward in the moving direction contributes to guidance to greater extent than the LED 52 located just beside the people.

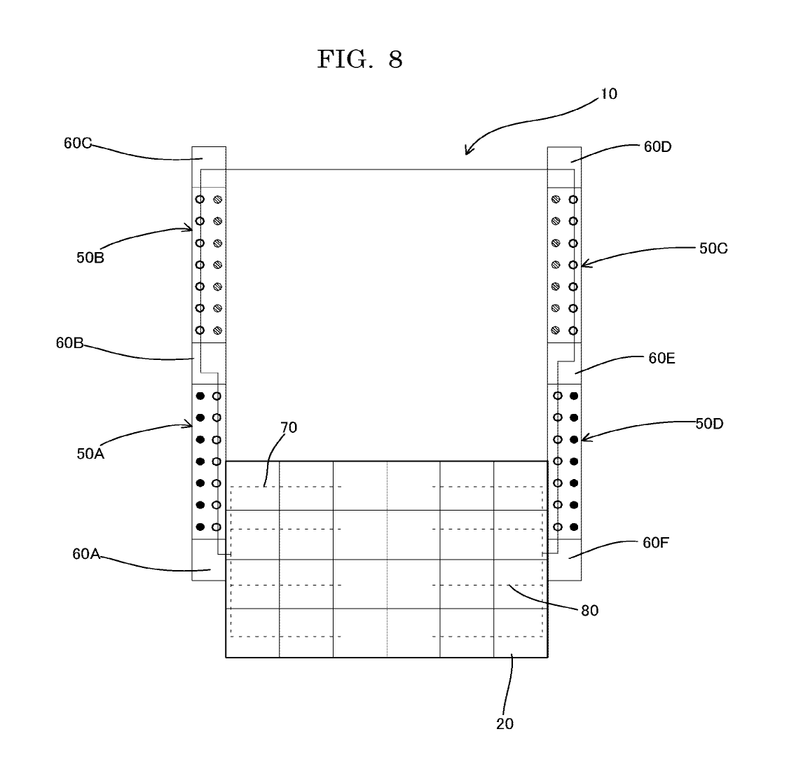

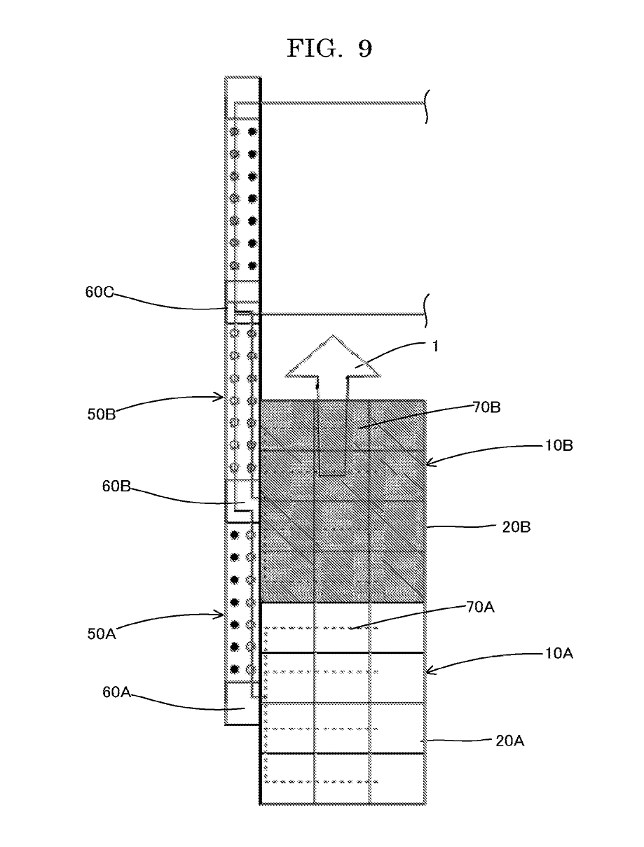

Wiring in a guidance apparatus which is formed by adding a relay board to the guidance apparatus illustrated in FIG. 7 will now be described. FIG. 8 is a schematic view illustrating one exemplary wiring of the guidance apparatus of FIG. 7, the guidance apparatus including a relay board. FIG. 9 is an explanatory view illustrating a lightning state of light sources in a left half of a guidance apparatus under a condition in which two guidance apparatuses of FIG. 8 are continuously coupled to each other.

As illustrated in FIG. 8, the LED arrays 50 are coupled to each other via a relay board 60. In wiring of the guidance apparatus 10, a wire 70 is wired from the electric-power-generating element 30 via a relay board 60A, which is illustrated at a left side in this drawing, to LEDs in an inner row of a LED array 50A and then to a relay board 60B. Then, the wire is wired from the relay board 60B through LEDs in an outer row of a LED array 50B to a relay board 60C. Then, the wire is wired from the relay board 60C to a relay board 60D, which is illustrated at a right side in this drawing. Then, the wire is wired from the relay board 60D through LEDs in an outer row of a LED array 50C to a relay board 60E. Then, the wire is wired from the relay board 60E through LEDs in an inner row of a LED array 50D to a relay board 60F. Then, the wire is wired from the relay board 60F to a GND 80 of the panel 20.

The wiring described above enables the LED to light whenever any pressure is applied anywhere on the guidance apparatus 10.

Notably, when the LED array 50 is extended in the moving direction as illustrated in FIG. 8, the LED array 50 in the moving direction is lighted, but the LED array 50 in an opposite direction to the moving direction is not lighted. As a result, a wrong route is not indicated by light and people can be prevented from going in a wrong direction.

A specific method for lightning LEDs will now be described referring to FIG. 9. As illustrated in FIG. 9, when pressure is applied to the panel 20A of the guidance apparatus 10A, LEDs in the inner row of the LED array 50A and LEDs in the outer row of the LED array 50B are lighted. Next, when pressure is applied to the panel 20B of the guidance apparatus 10B, LEDs in the inner row of the LED array 50B and LEDs in the outer row of another forward LED array are lighted. By repeating the procedure described above, the LEDs in the moving direction can always light to guide people. It is advantageous to light the LEDs in the inner and outer rows separately as described above because a plurality of guidance apparatuses 10 can share one LED array.

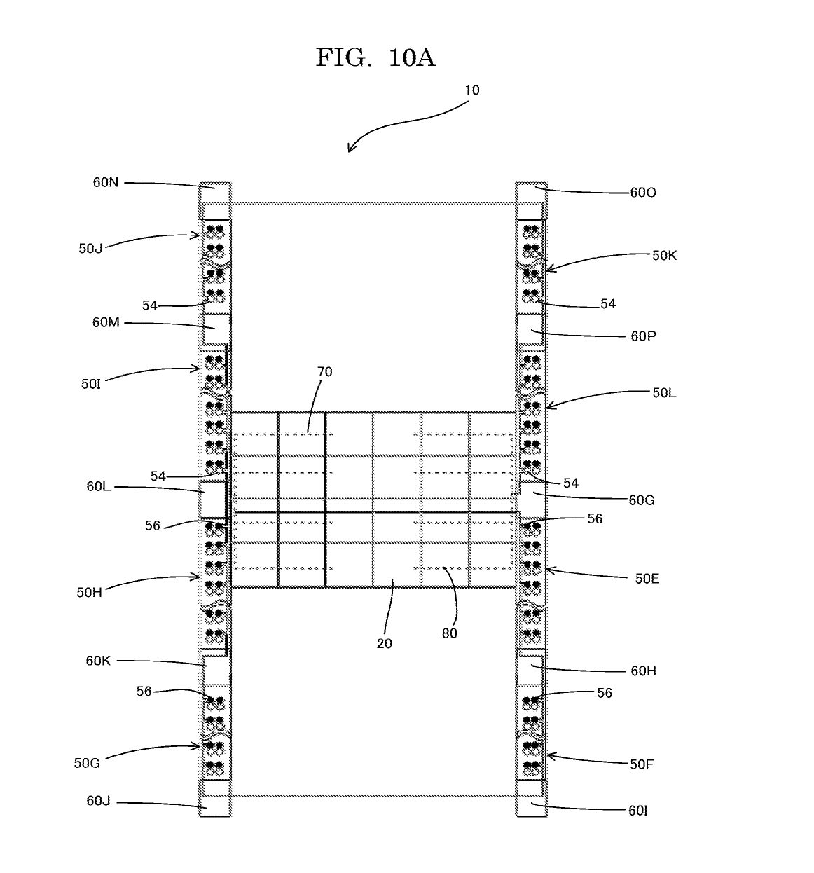

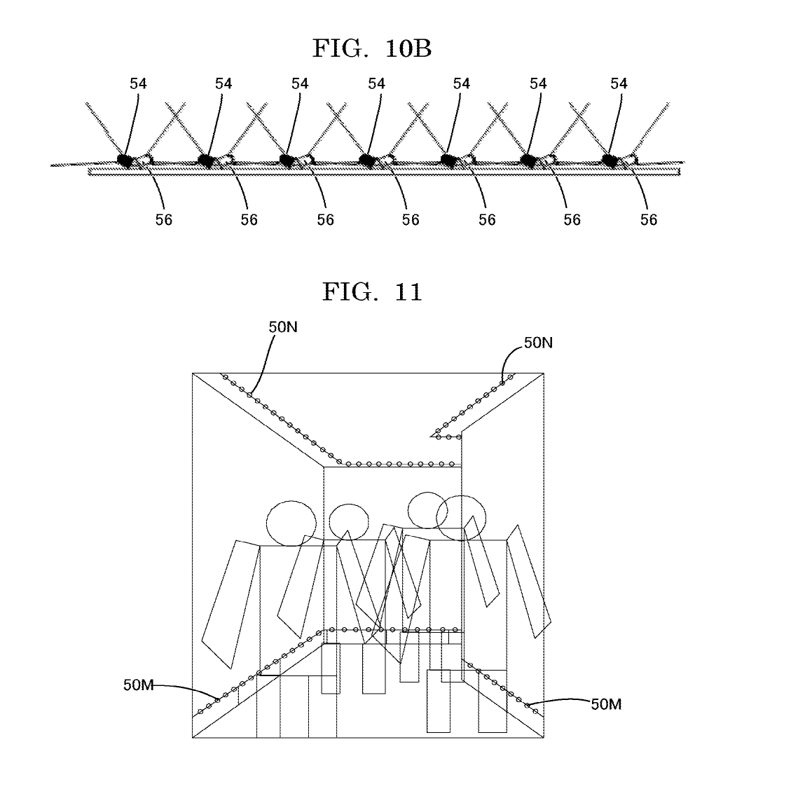

The LEDs 52 may be arranged in the LED array 50 as illustrated in FIGS. 10A and 10B. That is, the LEDs 52 each having the directivity of 60° or less may be divided into a first group 54 of light sources disposed obliquely to the same direction as the moving direction and a second group 56 of light sources disposed obliquely to an opposite direction to the moving direction. The first group 54 of light sources may emit light having a different color from light emitted from the second group 56 of light sources. In the case of employing such arrangement, for example, as in FIG. 10B, when the first group 54 of light sources includes a plurality of LEDs 52 emitting green light and disposed obliquely to the left and the second group 56 of light sources includes a plurality of LEDs 52 emitting red light and disposed obliquely to the right, assuming that the moving direction is toward the left, people can always visually recognize the green light emitted by the LEDs 52 of the first group 54 of light sources while the people go toward the left, and the people can visually recognize the red light emitted by the LEDs 52 of the second group 56 of light sources while the people go toward the right. That is, people can recognize that the people are going in the moving direction while the people visually recognize the green light. Meanwhile, people can recognize that the people are going in an opposite direction to the moving direction while the people visually recognize the red light. Therefore, the people can be prevented from going in the wrong direction. Notably, the first group 54 of light sources may be disposed in a shape of an arrow indicating the moving direction or an allowance sign and the second group 56 of light sources may be disposed in a shape of a prohibition sign in order to indicate the moving direction not only by color but also by design. The directivity of the LEDs 52 is not particularly limited and may be appropriately selected depending on the intended purpose, so long as the LEDs have the directivity so that, when the LEDs 52 are disposed obliquely as illustrated in FIG. 10B, the LEDs can be visually recognized only from the oblique direction. However, the directivity is preferably 60° or less.

One exemplary wiring of the guidance apparatus 10 illustrated in FIGS. 10A and 10B will now be described referring to FIG. 10A.

As illustrated in FIG. 10A, a wire 70 is wired from an electric-power-generating element (not illustrated) of the guidance apparatus 10 via a relay board 60G, which is illustrated at a right side in FIG. 10A, to LEDs of the second group 56 of light sources in an inner row of a LED array 50E disposed at a lower right, and then to a relay board 60H. Then, the wire is wired from the relay board 60H through LEDs of the second group 56 of light sources in an outer row of a LED array 50F to a relay board 60I. Then, the wire is wired from the relay board 60I to a relay board 60J, which is illustrated at a left side in this drawing. Then, the wire is wired from the relay board 60J through LEDs of the second group 56 of light sources in an outer row of a LED array 50G to a relay board 60K. Then, the wire is wired from the relay board 60K through LEDs of the second group 56 of light sources in an inner row of a LED array 50H to a relay board 60L. Then, the wire is wired from the relay board 60L through LEDs of the first group 54 of light sources in an inner row of a LED array 50I to a relay board 60M. Then, the wire is wired from the relay board 60M through LEDs of the first group 54 of light sources in an outer row of a LED array 50J to a relay board 60N. Then, the wire is wired from the relay board 60N to a relay board 60O, which is illustrated at a right side in this drawing. Then, the wire is wired from the relay board 60O through LEDs of the first group 54 of light sources in an outer row of a LED array 50K to a relay board 60P. Then, the wire is wired from the relay board 60P through LEDs of the first group 54 of light sources in an inner row of a LED array 50L to a relay board 60G and then to the panel 20 or a GND80 of the lower floor material.

FIG. 11 is a schematic view illustrating a condition in which light sources are also disposed on a ceiling.

When the guidance apparatus 10 is disposed only on a floor in the passage, people may not recognize a LED array 50M, which is disposed at a low level in the passage, in a crowd because the LED array is hidden behind forward walkers. However, in the crowd, pressure is applied to an increased area of the electric-power-generating element 30 to increase the amount of electric power generation. Therefore, when a LED array 50N is disposed on the ceiling as illustrated in FIG. 11, the LED array 50N disposed on the ceiling can be lighted utilizing electric power generated by a plurality of people even though only one person cannot generate electric power. In this arrangement, the LED array may be disposed so that LEDs which can light at a relatively low current (e.g., red or green) are disposed at the low level in the passage and LEDs which is less likely to light at a low current (e.g., blue or white) are coupled in series and disposed on the ceiling. When the amount of electric power generation is small, only the LEDs, which can light at a low current and disposed at the low level in the passage, are lighted. However, when the amount of electric power generation is increased and thus an amount of current is also increased, the LED disposed on the ceiling can be also lighted.

The LED array 50M disposed at the low level may be coupled to the LED array 50N disposed on the ceiling in parallel via a switch. The LED array 50N disposed on the ceiling is normally turned off so as to light only the LED array 50M disposed at the low level. When the amount of electric power generation is increased beyond a threshold value, the switch is turned on to supply a current to the LED array 50N disposed on the ceiling.

### (Embodiments of Guidance System)

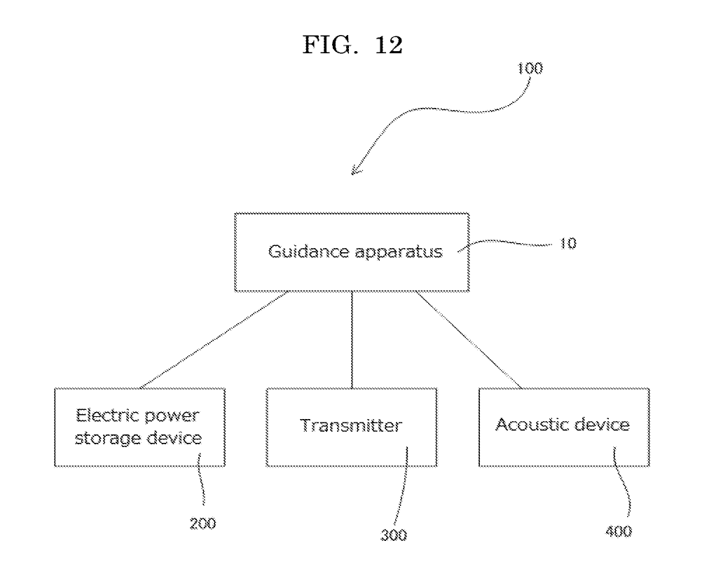

A guidance system according to the present invention will now be described referring to FIG. 12. FIG. 12 is an arrangement diagram illustrating a guidance system according to one embodiment of the present invention.

As illustrated in FIG. 12, a guidance system 100 includes a guidance apparatus 10, an electric power storage device 200, a transmitter 300, and an acoustic device 400.

The electric power storage device 200 is configured to store electric power generated by the guidance apparatus 10.

The transmitter 300 is configured to transmit a signal to another device (not illustrated) using the electric power generated by the guidance apparatus 10.

The acoustic device 400 is configured to make a sound using the electric power generated by the guidance apparatus 10.

The guidance system 100 according to the present invention includes the guidance apparatus 10, so that the electric power storage device 200 can store electric power using the electric power generated by the guidance apparatus 10. When the guidance apparatus 10 is disposed on the floor in the passage, the presence of a person who is passing through the passage can be recognized by a signal transmitted from the transmitter 300. By disposing the guidance apparatus 10 in the guidance system 100 on the floor of a region to be decorated, sound effects may be made in response to pressure applied to the guidance apparatus 10 by a walker.

Aspects of the present invention are, for example, as follows.

<1> A guidance apparatus including:
a panel configured to be disposed on at least one of a floor on a predetermined region and a wall on a predetermined region in a passage;
an electric-power-generating element configured to be disposed on an opposite side of the panel to a side to which external force is applied, the electric-power-generating element having flexibility; and
at least one light source configured to be electrically coupled to the electric-power-generating element.
<2> The guidance apparatus according to <1>,
wherein the electric-power-generating element includes a first electrode, an intermediate layer, and a second electrode, the intermediate layer being between the first electrode and the second electrode, and
wherein the intermediate layer includes silicone rubber.
<3> The guidance apparatus according to <1> or <2>,
wherein the panel is divided into a plurality of panels.
<4> The guidance apparatus according to <3>,
wherein each of the plurality of panels has a size of 25 cm×25 cm.
<5> The guidance apparatus according to <3> or <4>,
wherein the electric-power-generating element is disposed on a back side of each of the plurality of panels.
<6> The guidance apparatus according to any one of <1> to <5>,
wherein the at least one light source includes a plurality of light sources, and
wherein the plurality of light sources are disposed in parallel to and in contact with sides of a peripheral edge of the panel on the predetermined region, the sides being in parallel to a moving direction on the passage.
<7> The guidance apparatus according to <6>,
wherein the plurality of light sources are disposed for a length from 1.5 times through 2 times as long as a length of the region in a length direction of the plurality of panels on the region, the length direction being in parallel to the moving direction on the passage.
<8> The guidance apparatus according to <6> or <7>,
wherein the plurality of light sources include a first group of light sources and a second group of light sources,
wherein the first group of light sources are disposed obliquely to a same direction as the moving direction on the passage and the second group of light sources are disposed obliquely to an opposite direction to the moving direction on the passage, or
wherein the first group of light sources are disposed obliquely to an opposite direction to the moving direction on the passage and the second group of light sources are disposed obliquely to a same direction as the moving direction on the passage.
<9> The guidance apparatus according to any one of <1> to <8>,
wherein the at least one light source includes a plurality of light sources, and the plurality of light sources include at least one light source disposed on at least one of the floor and the wall, and at least one light source disposed on a ceiling.
<10> A guidance system including
the guidance apparatus according to any one of <1> to <9>.
<11> The guidance apparatus according to any one of <1> to <9>,
wherein the at least one light source is at least one light emitting diode (LED).
<12> The guidance apparatus according to any one of <1> to <9>,
wherein the at least one light source forms a LED array including a plurality of LEDs.
<13> The guidance apparatus according to <11> or <12>,
wherein the LEDs emit light of green, red, white, or blue.
<14> The guidance apparatus according to any one of <1> to <9> and <11> to <13>,
wherein a lower floor material is disposed under the electric-power-generating element.
<15> The guidance apparatus according to any one of <1> to <9> and <11> to <14>,
wherein the panel includes a tatami mat, a textile, stone, a resin material, a natural material, or an elastic body.
<16> The guidance apparatus according to any one of <1> to <9> and <11> to <15>,
wherein the passage is an indoor passage.
<17> The guidance apparatus according to any one of <1> to <9> and <11> to <16>,
wherein the passage is an outdoor passage.
<18> The guidance system according to <10>,
wherein the guidance system includes an electric power storage device.
<19> The guidance system according to <10>,
wherein the guidance system includes a transmitter.
<20> The guidance system according to <10>,
wherein the guidance system includes an acoustic device.

The guidance apparatus according to any one of <1> to <9> and <11> to <17> and the guidance system according to any one of <10> and <18> to <20> aim to solve the above existing problems and achieve the following object. That is, the guidance apparatus and the guidance system have an object to provide a guidance apparatus and a guidance system including an electric-power-generating element with high durability without being broken, the electric-power-generating element being configured to generate a large amount of electric power.

What is claimed is:

1. A guidance apparatus comprising:
a panel configured to be disposed on at least one of a floor on a predetermined region and a wall on a predetermined region in a passage;
an electric-power-generating element configured to be disposed on an opposite side of the panel to a side to which external force is applied, the electric-power-generating element having flexibility; and
at least one light source configured to be electrically coupled to the electric-power-generating element.

2. The guidance apparatus according to claim 1,
wherein the electric-power-generating element comprises a first electrode, an intermediate layer, and a second electrode, the intermediate layer being between the first electrode and the second electrode, and
wherein the intermediate layer comprises silicone rubber.

3. The guidance apparatus according to claim 1,
wherein the panel is divided into a plurality of panels.

4. The guidance apparatus according to claim 3,
wherein each of the plurality of panels has a size of 25 cm×25 cm.

5. The guidance apparatus according to claim 3,
wherein the electric-power-generating element is disposed on each of the plurality of panels, and
wherein the electric-power-generating element is disposed on the opposite side of the panel to the side to which external force is applied.

6. The guidance apparatus according to claim 1,
wherein the at least one light source comprises a plurality of light sources, and
wherein the plurality of light sources are disposed in parallel to and in contact with sides of a peripheral edge of the panel on the predetermined region, the sides being in parallel to a moving direction on the passage.

7. The guidance apparatus according to claim 6,
wherein the plurality of light sources are disposed for a length from 1.5 times through 2 times as long as a length of the region in a length direction of the plurality of panels on the region, the length direction being in parallel to the moving direction on the passage.

8. The guidance apparatus according to claim 6,
wherein the plurality of light sources comprise a first group of light sources and a second group of light sources,
wherein the first group of light sources are disposed obliquely to a same direction as the moving direction on the passage and the second group of light sources are disposed obliquely to an opposite direction to the moving direction on the passage, or
wherein the first group of light sources are disposed obliquely to an opposite direction to the moving direction on the passage and the second group of light sources are disposed obliquely to a same direction as the moving direction on the passage.

9. The guidance apparatus according to claim 1,
wherein the at least one light source comprises a plurality of light sources, and the plurality of light sources comprise at least one light source disposed on at least one of the floor and the wall, and at least one light source disposed on a ceiling.

10. A guidance system comprising
a guidance apparatus comprising:
a panel configured to be disposed on at least one of a floor on a predetermined region and a wall on a predetermined region in a passage;
an electric-power-generating element configured to be disposed on an opposite side of the panel to a side to which external force is applied, the electric-power-generating element having flexibility; and
at least one light source configured to be electrically coupled to the electric-power-generating element.
